(19) United States
(12) Patent Application Publication
(10) Pub. No.: US 2007/0257347 A1
(43) Pub. Date: Nov. 8, 2007

(54) CHIP STRUCTURE AND FABRICATING PROCESS THEREOF

(76) Inventor: Hui-Ling Chang, Chiayi County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(21) Appl. No.: 11/309,053

(22) Filed: Jun. 14, 2006

(30) Foreign Application Priority Data
May 2, 2006 (TW) 95115552

(51) Int. Cl. H01L 23/20

(52) U.S. Cl. 257/682

(57) ABSTRACT

A chip structure comprising a substrate, a conductive layer, a plurality of bumps and a trap layer is provided. The substrate has a plurality of pads and the conductive layer is disposed on the pads. The bumps are disposed on the conductive layer above the pads and the trap layer is disposed between two adjacent bumps. In addition, a process of fabricating the chip structure is provided.

### CROSS-REFERENCE TO RELATED APPLICATION

This application claims the priority benefit of Taiwan application serial no. 95115552, filed on May 2, 2006. All disclosure of the Taiwan application is incorporated herein by reference.

### BACKGROUND OF THE INVENTION

1. Field of the Invention

The present invention relates to a semiconductor structure and fabricating process thereof, and more particularly, to a chip structure and fabricating process thereof.

2. Description of Related Art

In general, flexible carrier packaging techniques, including the tape automated bonding (TAB) technique and chip-on-film (COF) bonding technique, are used in many different types of applications. Using the process of joining a liquid crystal display panel with a driving chip as an example, the method includes first providing a flexible substrate; the flexible substrate has a surface with a circuit layer, and the circuit layer has a plurality of inner leads. Then, a driving chip is provided. The driving chip has an active surface with a plurality of gold bumps thereon. After that, the driving chip is disposed on the flexible substrate so that the gold bumps are connected to the corresponding inner leads. Next, underfill material is injected to fill the space between the driving chip and the flexible substrate. Afterward, a punching process is performed to cut the flexible substrate with chips thereon into a plurality of independent chip packages. Subsequently, individual chip package is bonded to a liquid crystal panel to form a liquid crystal display module. The driving chip is electrically connected to the liquid crystal panel via the flexible substrate.

However, in the process of fabricating the chip, the active surface of the driving chip may be contaminated by chemical substances or particulate impurities. Thus, the underfill material may not form a tight contact with the active surface of the driving chip after the filling process. When the liquid crystal display module operates, a portion of the gold may grow a finger-like extension from the gold bumps into the gap between the driving chip and the underfill due to the action of electric field, contaminants (for example, dust particles with halogen-containing ions) and moisture. When the outgrowing finger-like extension of gold comes into contact with other bumps, a micro short circuit between the gold bumps will easily occur. Ultimately, the liquid crystal display module will produce an abnormal display.

### SUMMARY OF THE INVENTION

Accordingly, at least one objective of the present invention is to provide a chip structure capable of resolving short circuit problem due to the action of electric field, contaminants and moisture.

At least another objective of the present invention is to provide a process for fabricating a chip structure capable of increasing the production yield of the chip.

To achieve these and other advantages and in accordance with the purpose of the invention, as embodied and broadly described herein, the invention provides a chip structure. The chip structure includes a substrate, a conductive layer, a plurality of bumps and a trap layer. The substrate has a plurality of pads and the conductive layer is disposed on the pads. The bumps are disposed on the conductive layer above the pads and the trap layer is disposed between two adjacent bumps.

In one embodiment of the present invention, a plated seed layer is disposed between the conductive layer and the bumps, and both the plated seed layer and the bumps are fabricated using a same material.

In one embodiment of the present invention, the bumps are gold bumps, for example.

In one embodiment of the present invention, the material constituting the conductive layer includes a titanium/tungsten alloy, for example.

In one embodiment of the present invention, the material constituting the conductive layer includes an inorganic conductive material, for example.

In one embodiment of the present invention, the material constituting the pads includes aluminum, for example.

In one embodiment of the present invention, the material constituting the trap layer includes a titanium/tungsten alloy, for example.

In one embodiment of the present invention, the conductive layer is, for example, a metal-stacked layer. The metal-stacked layer comprises a plurality of stacked metallic layers. Furthermore, the material constituting the bottommost metallic layer of the metal-stacked layer includes a titanium/tungsten alloy, for example.

In one embodiment of the present invention, the material constituting the bottommost metallic layer of the metal-stacked layer and the trap layer include an inorganic conductive material, for example.

The present invention also provides a process of fabricating a chip structure comprising the following steps. First, a substrate having a plurality of pads thereon is provided. Then, a conductive layer is formed on the substrate. Next, a bump is formed on the conductive layer above each of the pads. Afterwards, a portion of the exposed conductive layer outside the bumps is removed to form a trap layer between two adjacent bumps.

In one embodiment of the present invention, after forming the bumps, further includes the following steps. First, a mask layer is formed on part of the conductive layer between two adjacent bumps. Then, part of the exposed conductive layer outside the mask layer between two adjacent bumps is removed. After that, the mask layer is removed to form a trap layer between two adjacent bumps.

In one embodiment of the present invention, the method of forming the bumps includes the following steps. First, a mask layer is formed on the substrate. The mask layer has a plurality of openings that exposes the conductive layer above the pads. Then, bumps are formed within the openings. Next, the mask layer is removed.

In one embodiment of the present invention, the bumps are formed in the openings by performing an electroplating process.

In one embodiment of the present invention, before forming the bumps in the openings, further includes forming a plated seed layer on the conductive layer. The plated seed layer is formed on the conductive layer by performing a sputtering process.

In one embodiment of the present invention, the conductive layer can be a metal-stacked layer. The metal-stacked layer comprises a plurality of stacked metallic layers and the bottommost layer of the metal-stacked layer is a bottom metallic layer. Moreover, the following steps are carried out after forming the bumps on the metal-stacked layer. First, the remaining exposed metallic layers outside the bumps and above the bottom metallic layer are removed. Then, part of the exposed bottom metallic layers outside the bumps is removed to form a trap layer between two adjacent bumps.

In the present invention, a trap layer is formed between two adjacent bumps so that moisture or contaminants (for example, the dust particles with halogen-containing ions) attached to the chip structure can react with the trap layer between two adjacent bumps. Hence, the contaminants are unlikely to react with bumps that will produce a short circuit between adjacent bumps. Therefore, the trap layer in the present invention is able to maintain electrical isolation between two adjacent bumps within the chip structure so that overall yield of the chip is increased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1H are schematic cross-sectional views showing the steps for fabricating a chip structure according to one preferred embodiment of the present invention.

FIGS. 2A through 2E are schematic cross-sectional views showing the steps for fabricating another chip structure according to one preferred embodiment of the present invention.

FIGS. 3A and 3B are schematic cross-sectional views showing the steps for fabricating a trap layer according to one preferred embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

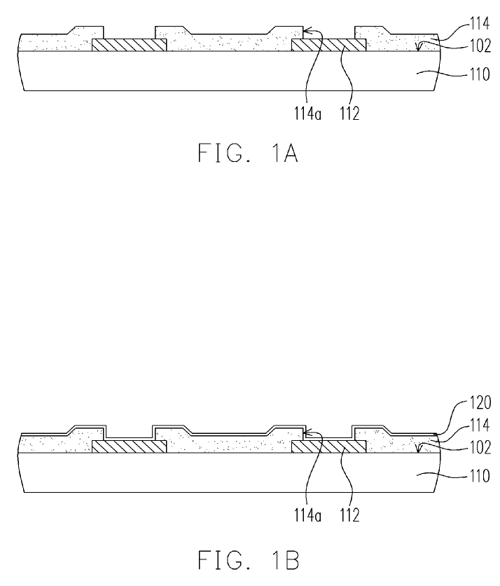

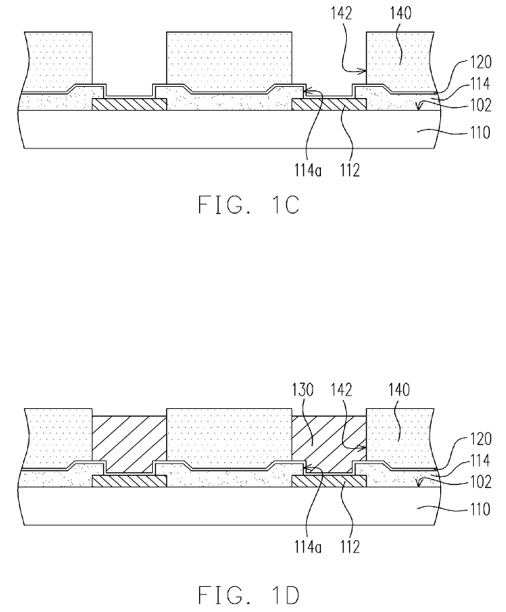

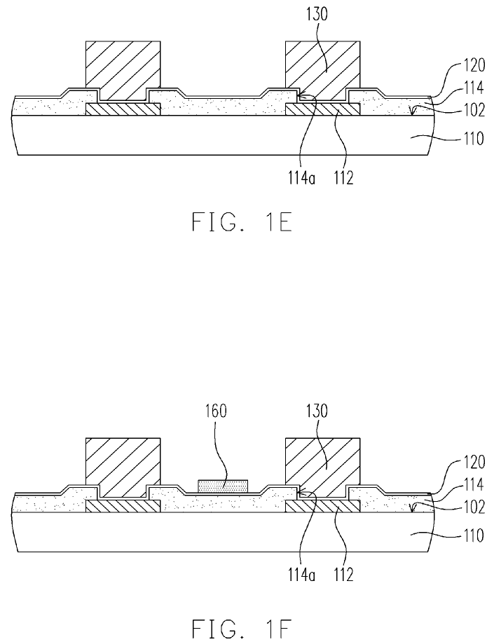

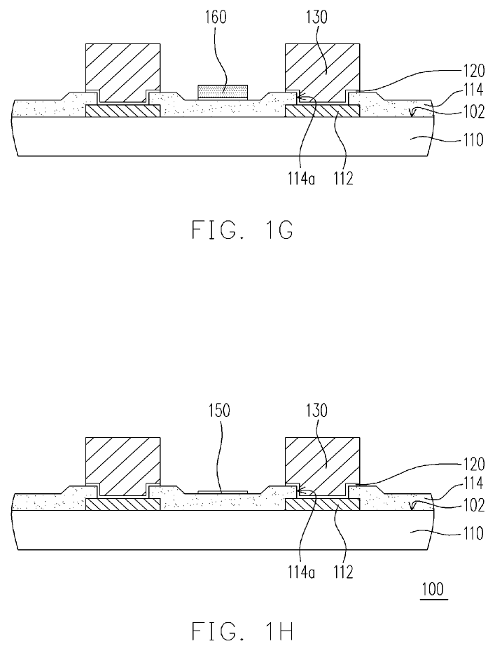

FIGS. 1A through 1H are schematic cross-sectional views showing the steps for fabricating a chip structure according to one preferred embodiment of the present invention. First, as shown in FIG. 1A, a substrate 110 is provided. The substrate 110 is, for example, a wafer or a substrate having a surface 102. Furthermore, the substrate 110 has a plurality of pads disposed on the surface 102. The material constituting the pads 112 includes, for example, aluminum. In addition, a passivation layer 114 is also formed on the surface 102 of the substrate 110 for protecting the circuit (not shown) in the outermost layer of the substrate 110. The passivation layer 114 may have a plurality of openings 114a that exposes the corresponding pads 112. Then, as shown in FIG. 1B, a conductive layer 120 is formed on the substrate 110. The material constituting the conductive layer 120 includes, for example, a titanium/tungsten alloy.

Next, as shown from FIGS. 1C through 1E, a bump 130 is formed on the conductive layer 120 above each of the pads 112. The material constituting the bumps 130 includes, for example, gold. In the following, the method of forming the bumps 130 on the conductive layer 120 is explained in more detail. For example, the present embodiment includes providing a mask layer 140 over the substrate 110 (refer to FIG. 1C), wherein the mask layer 140 has a plurality of openings 142 that exposes the conductive layer 120 above the pads 112. Then, as shown in FIG. 1D, bumps 130 are formed inside the openings 132. The bumps 130 are formed inside the openings 142, for example, by performing an electroplating process. After that, as shown in FIG. 1E, the mask layer 130 (refer to FIG. 1D) is removed to complete the process of fabricating the bumps 130.

After forming a bump 130 on the conductive layer 120 above each of the pads 112 (as shown in FIG. 1E), the steps as shown in FIGS. 1F through 1H are carried out in sequence. First, part of the exposed conductive layer 120 outside the bumps 130 is removed to form a trap layer 150 between two adjacent bumps 130. The trap layer 150 has a thickness of about 1000 Å. For example, the method of forming the trap layer 150 includes forming a mask layer 160 (as shown in FIG. 1F) on part of the conductive layer 120 between two adjacent bumps 130. Then, as shown in FIG. 1G, part of the exposed conductive layer 120 outside the mask layer 160 between the two adjacent bumps 130 is removed. Afterwards, as shown in FIG. 1H, the mask layer 160 (as shown in FIG. 1G) is removed to form a trap layer 150 between the two adjacent bumps 130. Both the trap layer 150 and the conductive layer 120 are fabricated using a same material (for example, a titanium/tungsten alloy). After performing the foregoing steps, a complete chip structure 100 according to the present embodiment is produced.

It should be noted that the trap layer 150 is made of titanium/tungsten alloy. Hence, moisture in the air or contaminants (for example, dust particles with halogen-containing ions) may easily react with the titanium/tungsten alloy so that the moisture or contaminants attached to the passivation layer 114 can easily react with the trap layer 150 between two adjacent bumps 130. As a result, the probability of the moisture in the air or contaminants reacting with the gold bumps 130 is substantially minimized. In other words, when the chip structure 100 operates, it is not so easy for part of the bump material to grow from the bumps 130 and lead to a short circuit between two neighboring bumps 130 due to the action provided by electric field, contaminants and moisture. Therefore, in the present embodiment, the two adjacent bumps 130 are maintained in an electrical isolation relation so that the chip structure 100 can have a higher production yield and any electronic devices with the chip structure 100 can have a better product quality. Furthermore, the present invention does not provide any particular restriction on the type of material forming the trap layer 150. Any inorganic conductive materials with properties suitable for reacting with moisture in the air or contaminants should be included within the scope of the present invention.

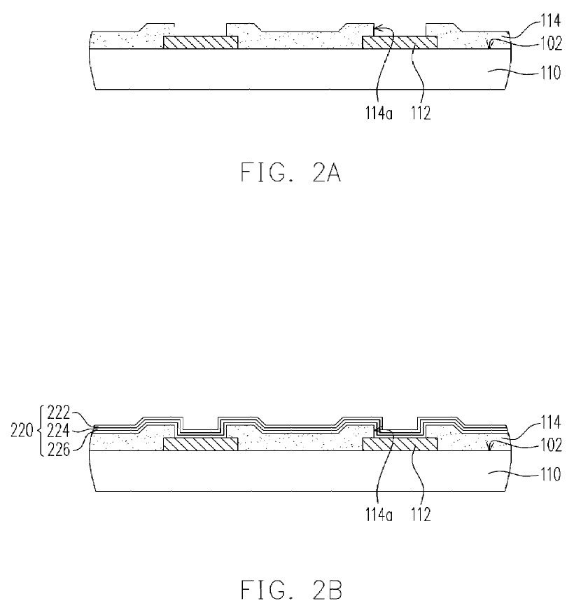

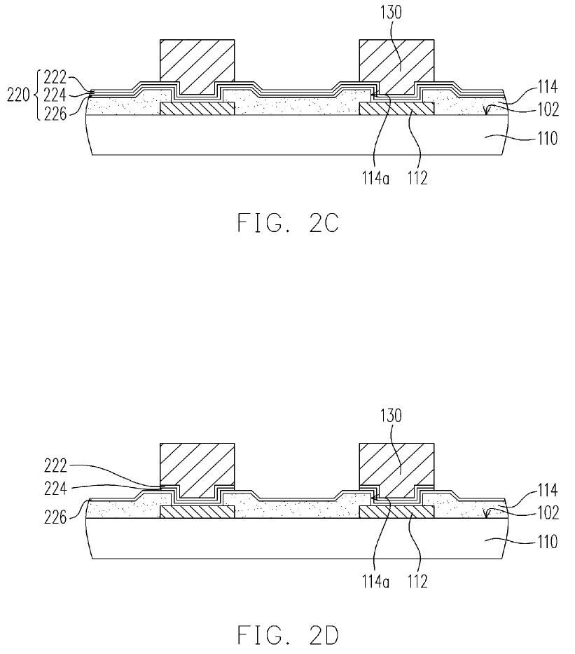

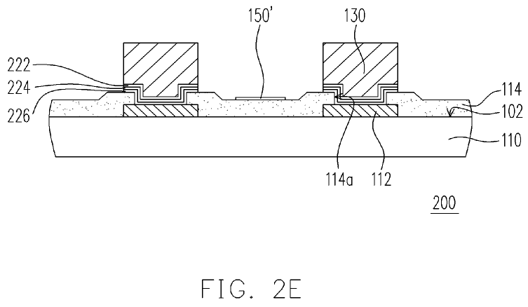

The process as shown from FIGS. 1A through 1F is not the only method for fabricating a chip structure. In the following, other methods of fabricating the chip structure according to the present invention are described. To simplify explanations, identical devices are labeled with the same references. FIGS. 2A through 2E are schematic cross-sectional views showing the steps for fabricating another chip structure according to one preferred embodiment of the present invention. The process of fabricating the chip structure in the present embodiment is very similar to the foregoing process. The main difference is that the conductive layer in the present embodiment is a metal-stacked layer. In the following, the process of fabricating the chip structure according to the present embodiment is described in detail.

First, as shown in FIG. 2A, a substrate 110 is provided. Then, as shown in FIG. 2B, a metal-stacked layer 220 is formed on the substrate 110. In the present embodiment, the metal-stacked layer 220 comprises a stack of metallic layers 222, 224 and 226, for example. The material constituting the bottommost metallic layer 226 of the metal-stacked layer 220 includes, for example, a titanium/tungsten alloy. Next, as shown in FIG. 2C, a bump 130 is formed on the metal-stacked layer 220 above each of the pads 112. Since the method of forming the bumps 130 is identical to the bump process as shown from FIGS. 1C to 1E, a detailed description is omitted in the present embodiment. In one embodiment, the metallic layer 222 for bonding with the bumps 130 is, for example, a plated seed layer made of gold. The metallic layer 222 is formed on the metallic layer 224 by applying a sputtering technique so that the bumps 130 similarly made of gold can bond tightly to the corresponding pads 112 through the metal-stacked layer 220.

After forming the bumps 130 (as shown in FIG. 2C) on the metal-stacked layer 220, the remaining exposed metallic layers 222 and 224 (as shown in FIG. 2D) above the metallic layer 226 outside the bumps 130 are removed. After that, as shown in FIG. 2E, part of the exposed metallic layer 226 outside the bumps 130 is removed to form a trap layer 150′ between two adjacent bumps 130. Hence, the process of fabricating the chip structure 200 according to the present embodiment is completed. Since the method of removing part of the metallic layer 226 to form the trap layer 150′ is identical to the process of fabricating the chip structure as shown in FIG. 1F to 1H, a detailed description is omitted.

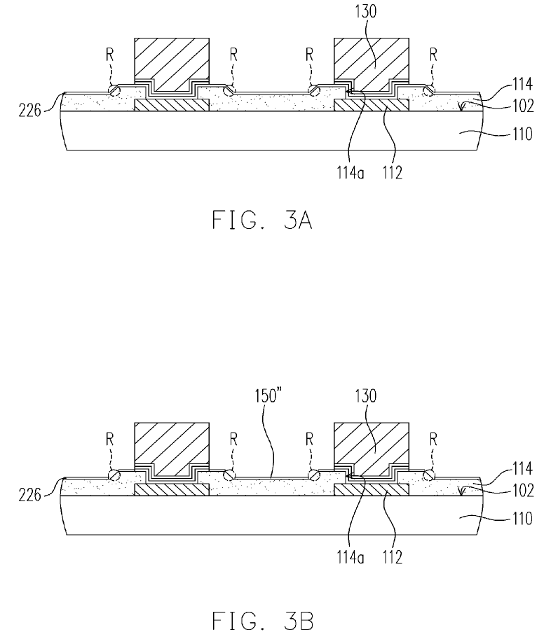

In addition, the present invention also provides a method of fabricating a trap layer that can produce the trap layer efficiently. FIGS. 3A and 3B are schematic cross-sectional views showing the steps for fabricating a trap layer according to one preferred embodiment of the present invention. As shown in FIG. 3A, the passivation layer 114 on the substrate 110 has an uneven top surface (the upper surface of the passivation layer 114 covering the pads 112 is higher than the top surface of the passivation layer 114 elsewhere). Therefore, the thickness of the metallic layer 226 on the passivation layer 114 is also uneven (for example, the metallic layer 226 in the R region is thinner). In the present embodiment, utilizing the non-uniform thickness of the metallic layer 226 on the passivation layer 114, the metallic layer 226 in the R region is removed (as shown in FIG. 3B) by etching the metallic layer 226 for a suitable period of time. Meanwhile, the thicker metallic layer 226 outside the R region is transformed into a thinner metallic layer that covers part of the passivation layer 114 after etching for a suitable time period. The thin metallic layer serves as a trap layer 150″ (the trap layer 150″ has a thickness between about 10 to 80 Å). Similar to the foregoing trap layer 150, the trap layer 150″ readily reacts with moisture in the air or contaminants (for example, dust particles with halogen-containing ions). Consequently, any moisture or contaminants attached to the passivation layer 114 can react with the trap layer 150″ between two adjacent bumps 130 and significantly reduce the reaction between moisture in the air or contaminants with the gold bumps 130.

In summary, the present invention provides a trap layer capable of reacting with moisture in the air or contaminants between two adjacent bumps. Therefore, when the chip structure is in an operating mode, the chance of a reaction between the moisture and contaminants on the substrate with the bumps is significantly reduced. As a result, bump material is harder to grow out from the bumps and unlikely to lead to a short circuit between two adjacent bumps. Compared with the conventional technique, two adjacent bumps in the chip structure of the present invention are able to maintain electrical isolation. Hence, yield of the chip is increased and any electronic device equipped with the chip structure of the present invention can have a better product quality.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A process of fabricating a chip structure, comprising:
providing a substrate, wherein the substrate has a plurality of pads thereon;
forming a conductive layer on the substrate;
forming a bump on the conductive layer above each of the pads; and
removing part of the exposed conductive layer outside the bumps so that a trap layer is formed between two adjacent bumps.

2. The process of claim 1, wherein the method of forming the bumps comprises:
providing a mask layer on the substrate, wherein the mask layer has a plurality of openings that exposes the conductive layer above the pads;
forming the bumps inside the openings; and
removing the mask layer.

3. The process of claim 2, wherein the method of forming bumps inside the openings comprises performing an electroplating process.

4. The process of claim 2, wherein before forming the bumps inside the openings, further comprises forming a plated seed layer on the conductive layer.

5. The process of claim 4, wherein the method of forming the plated seed layer comprises performing a sputtering process.

6. The process of claim 1, wherein after forming the bumps, further comprises:
providing a mask layer on part of the conductive layer between two adjacent bumps;
removing part of the exposed conductive layer outside the mask layer between two adjacent bumps; and
removing the mask layer to form the trap layer between two adjacent bumps.

7. The process of claim 1, wherein the conductive layer is a metal-stacked layer comprising a stack of metallic layers such that the bottommost layer of the metal-stack layer is a bottom metallic layer, and after forming the bumps on the metal-stacked layer, further comprises:
removing the remaining exposed metallic layers above the bottom metallic layer outside the bumps; and
removing part of the exposed bottom metallic layer outside the bumps to form the trap layer between two adjacent bumps.

8. A chip structure, comprising:
a substrate, having a plurality of pads thereon;
a conductive layer, disposed on the pads;
a plurality of bumps, disposed on the conductive layer above the bumps; and
a trap layer, disposed between two adjacent bumps.

9. The chip structure of claim 8, wherein a plated seed layer is disposed between the conductive layer and the bumps.

10. The chip structure of claim 9, wherein the material constituting the plated seed layer and the bumps is the same.

11. The chip structure of claim 8, wherein the bumps are gold bumps.

12. The chip structure of claim 8, wherein the material constituting the conductive layer is a titanium/tungsten alloy.

13. The chip structure of claim 8, wherein the material constituting the conductive layer is an inorganic conductive material.

14. The chip structure of claim 8, wherein the material constituting the pads is aluminum.

15. The chip structure of claim 8, wherein the material constituting the trap layer is a titanium/tungsten alloy.

16. The chip structure of claim 8, wherein the conductive layer is a metal-stacked layer comprising a stack of metallic layers such that the bottommost metallic layer of the metal-stacked layer is a titanium/tungsten alloy.
